(19) United States
(12) Patent Application Publication
(10) Pub. No.: US 2014/0339598 A1
(43) Pub. Date: Nov. 20, 2014

(54) NITRIDE-BASED LIGHT-EMITTING ELEMENT COMPRISING A CARBON-DOPED P-TYPE NITRIDE LAYER

(71) Applicant: ILJIN LED CO., LTD., Ansan-si, Gyeonggi-do (KR)

(72) Inventors: Jung-Won Park, Yongin-si (KR); Sung-Hak Yi, Incheon (KR); Tae-Wan Kwon, Seoul (KR)

(73) Assignee: ILJIN LED CO.,LTD., Ansan-si, Gyeonggi-do (KR)

(21) Appl. No.: 14/367,587

(22) PCT Filed: Dec. 27, 2012
(86) PCT No.: PCT/KR2012/011546

§ 371 Date: Jun. 20, 2014

(30) Foreign Application Priority Data
Dec. 30, 2011 (KR) 10-2011-0147241

(51) Int. Cl. H01L 33/32; H01L 33/00; H01L 33/02

(52) U.S. Cl. CPC H01L 33/32; H01L 33/025; H01L 33/0075
USPC 257/101; 438/37

(57) ABSTRACT

The present invention relates to a nitride-semiconductor light-emitting element in which a p-type nitride layer is doped with carbon, and to a production method therefor. More specifically, the present invention relates to a nitride-semiconductor light-emitting element comprising a p-type nitride layer formed from a nitride having a high concentration of free holes as the carbon is auto-doped in accordance with adjustment of the rate of flow of a nitrogen source. The nitride-semiconductor light-emitting element of the present invention can provide a high free-hole concentration, which is difficult to achieve with conventional single p-type dopants, and can therefore lower the resistance and increase the light efficiency of the light-emitting element.

### TECHNICAL FIELD

The present invention relates to a nitride semiconductor light emitting device with a carbon-doped p-type nitride layer and a method of manufacturing the same and, more particularly, to a nitride semiconductor light emitting device that includes a p-type nitride layer formed of a nitride having a high free-hole concentration by adjusting the flow rate of an ammonia source such that carbon is auto-doped into the nitride, and a method of manufacturing the same. The nitride semiconductor light emitting device may be used for blue LEDs, UV LEDs, and the like.

### BACKGROUND ART

An example of a conventional nitride semiconductor device may include a GaN-based nitride semiconductor device, which is used for light emitting devices, such as blue or green LEDs, and high-speed switching and high-power devices, such as MESFETs, HEMTs, and the like.

Such a GaN-based nitride semiconductor device may be, for example, a nitride semiconductor light emitting device having an active layer of a multi-quantum well structure. A typical nitride semiconductor light emitting device includes a sapphire substrate, an n-type nitride layer, an active layer, and a p-type nitride layer. In addition, a transparent electrode layer and a p-side electrode are sequentially formed on an upper surface of the p-type nitride layer, and an n-side electrode is formed on an exposed surface of the n-type nitride semiconductor layer.

The GaN-based nitride semiconductor light emitting device emits light through recombination of electrons and holes injected into the active layer. To improve luminous efficacy of the active layer, the content of n-type dopants in the n-type nitride layer or the content of p-type dopants in the p-type nitride layer is increased to increase flow of electrons or holes into the active layer, as disclosed in Korean Patent Laid-open Publication No.2010-0027410 (Mar. 11, 2010).

However, the nitride semiconductor light emitting device with the increased content of n-type dopants in the n-type nitride layer or the increased content of p-type dopants in the p-type nitride layer can exhibit non-uniform current spreading and low hole-injection efficiency, thereby causing significant deterioration in luminous efficacy.

In particular, magnesium (Mg) is generally used as a p-type dopant. In this case, holes are excited from Mg acceptor level to the valence band by thermal energy and act as free-holes, thereby conducting electricity. Here, activation energy of Mg can be calculated as 0.17 eV. A principle of activating holes to be free-holes is shown in FIG. 1.

Ideally, when the content of p-type dopants is increased, the content of free-holes is increased in order to reduce resistance of p-GaN, as indicated by a dotted line in FIG. 2. However, it can be ascertained that, when the doping amount of Mg exceeds a certain level, the content of free-holes begins to decrease thereby increasing resistance, as indicated by a solid line. It is believed that this phenomenon is caused by self-compensation by electrons generated from nitrogen vacancies and Mg-nitrogen vacancy complexes.

In addition, a Mg-doped p-AlGaN has a low free-hole concentration of 5×10¹⁶/cm³ and thus exhibits properties similar to a non-conductor while often exhibiting n-type properties due to undesired contamination by impurities.

Thus, the free-hole concentration of a certain level or higher cannot be obtained by typical Mg doping. Therefore, there is a need for technology capable of increasing free-hole concentration to reduce resistance of a semiconductor light emitting device.

### DISCLOSURE

### Technical Problem

The present inventors have endeavored to develop a nitride semiconductor light emitting device having reduced resistance and improved luminous efficacy through improvement of free-hole concentration. As a result, it was found that adjustment of the flow rate of an ammonia source under specific conditions can lead to auto-doping of carbon into a nitride layer through minimization of pre-reaction of ammonia, trimethyl aluminum (TMAl) and bis(cyclopentadienyl)magnesium (Cp2Mg) sources while allowing co-doping of a p-type dopant and carbon into the nitride layer, thereby significantly increasing the free-hole concentration.

Therefore, an aspect of the present invention is to provide a nitride semiconductor light emitting device having a high free-hole concentration. Another aspect of the present invention is to provide a method of manufacturing the nitride semiconductor light emitting device.

### Technical Solution

In accordance with one aspect of the present invention, a nitride semiconductor light emitting device includes; an n-type nitride layer, an active layer formed on the n-type nitride layer, and a p-type nitride layer formed on the active layer, wherein the p-type nitride layer is formed of a nitride co-doped with a p-type dopant and carbon (C).

In accordance with another aspect of the present invention, a method of manufacturing a nitride semiconductor light emitting device includes: forming an n-type nitride layer on a substrate; forming an active layer on the n-type nitride layer; and forming a p-type nitride layer on the active layer, wherein, in formation of the p-type nitride layer, a nitrogen source is supplied at a lower flow late than in formation of the n-type nitride layer, such that a p-type dopant and carbon (C) are co-doped into the p-type nitride layer.

### Advantageous Effects

The nitride semiconductor light emitting device according to the present invention can provide a high free-hole concentration, which is difficult to realize with a typical p-type dopant alone, thereby reducing resistance while improving luminous efficacy of the light emitting device.

In particular, it is ascertained that, when the light emitting device according to the present invention includes a p-type nitride containing 20 mol % or more of Al in Group III, the light emitting device has a free-hole concentration of higher than 1×10¹⁸/cm³, thereby providing excellent light emitting properties. Thus, the light emitting device is expected to be used as UV-LEDs and the like in various ways.

### DESCRIPTION OF DRAWINGS

FIG. 1 is an energy band diagram showing that holes are activated from Mg acceptor level to be free-holes in a Mg-doped GaN layer.

FIG. 2 is a graph showing the relationship between free-hole concentration and doping amount of Mg.

FIG. 3 is a sectional view of a lateral type nitride semiconductor light emitting device according to a first embodiment of the present invention.

FIG. 4 is an energy band diagram showing activation pathways of holes in a GaN layer doped with Mg and carbon.

FIG. 5 is a sectional view of a vertical type nitride semiconductor light emitting device according to a second embodiment of the present invention

FIGS. 6A to 6D are sectional views illustrating a method of manufacturing the lateral type nitride semiconductor light emitting device according to the first embodiment of the present invention.

FIG. 7 is a graph showing profiles of magnesium and carbon in a nitride semiconductor light emitting device according to Example.

FIG. 8 is a graph showing profiles of magnesium and carbon in a nitride semiconductor light emitting device according to Comparative Example.

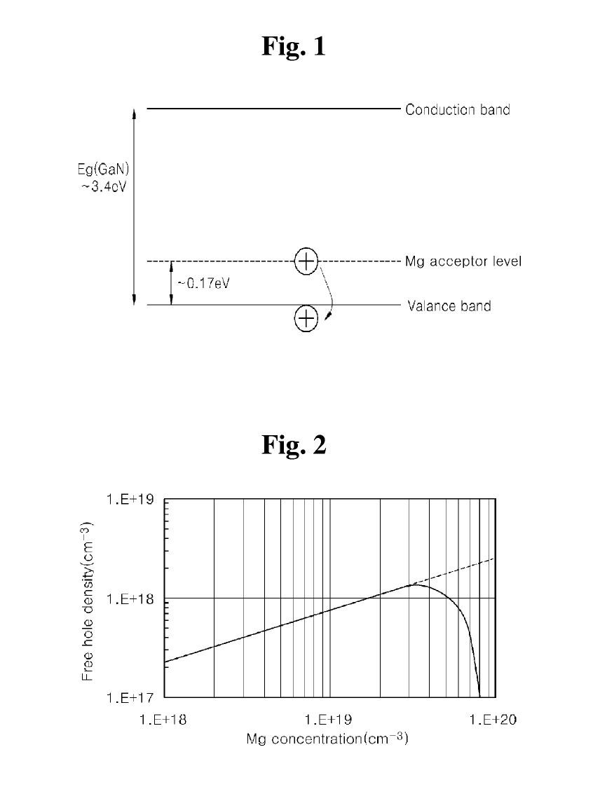

### DESCRIPTION OF REFERENCE NUMERALS

100: semiconductor light emitting device

110: substrate

120: buffer layer

130: n-type nitride layer

140: active layer

150: p-type nitride layer

160: transparent electrode layer

170: p-side electrode

180: n-side electrode

200: p-side electrode support layer

210: reflection layer

220: ohmic contact layer

230: p-type nitride layer

240: active layer

250: n-type nitride layer

260: n-side electrode

### BEST MODE

The above and other aspects, features, and advantages of the invention will become apparent from the detailed description of the following embodiments in conjunction with the accompanying drawings. It should be understood that the present invention is not limited to the following embodiments and may be embodied in different ways, and that the embodiments are given to provide complete disclosure of the present invention and to provide thorough understanding of the present invention to those skilled in the art. The scope of the present invention is limited only by the accompanying claims and equivalents thereof. Like components will be denoted by like reference numerals throughout the specification.

Hereinafter, exemplary embodiments of the present invention will be described in detail with reference to the accompanying drawings.

Nitride-Based Light Emitting Device

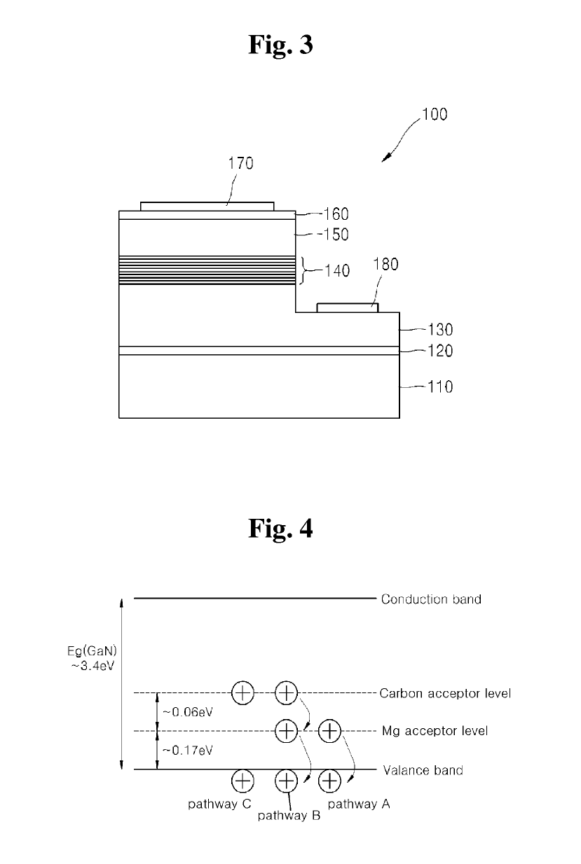

Referring to FIG. 3, a lateral type nitride semiconductor light emitting device 100 according to a first embodiment of the invention includes a buffer layer 120, an n-type nitride layer 130, an active layer 140, a p-type nitride layer 150, a transparent electrode layer 160, a p-side electrode 170, and an n-side electrode 180 in an upward direction of a substrate 110.

The buffer layer 120 is optionally formed to relieve lattice mismatch between the substrate 110 and the n-type nitride layer 130, and may be formed of, for example, MN or GaN.

The n-type nitride layer 130 is formed of a nitride doped with an n-type dopant on an upper surface of the substrate 110 or the buffer layer 120. The n-type dopant may include silicon (Si), germanium (Ge), tin (Sn), and the like. The n-type nitride layer 130 may have a stack structure in which, for example, a first layer formed of Si-doped n-type AlGaN or undoped AlGaN and a second layer formed of undoped or Si-doped n-type GaN are alternately stacked one above another. Although the n-type nitride layer 130 may be grown as a single n-type nitride layer, the n-type nitride layer 130 having the stack structure of the first and second layers alternately stacked one above another can act as a carrier restriction layer having good crystallinity without cracks.

The active layer 140 may be formed between the n-type nitride layer 130 and the p-type nitride layer 150, and may have a single quantum well structure or a multi-quantum well structure. In the active layer 140, light is generated by recombination of electrons supplied from the n-type nitride layer 130 and holes supplied from the p-type nitride layer 150. In this embodiment, the active layer 140 may have a multi-quantum well structure wherein quantum barrier layers and quantum well layers are formed of AlₓGa_{y}In_{z}N (x+y+z=1, 0≦x≦1, 0≦y≦1, 0≦z≦1). The active layer 140 having such a multi-quantum well structure can suppress spontaneous polarization by stress and deformation.

The p-type nitride layer 150 may be formed of a nitride co-doped with a p-type dopant and carbon (C), and may include a GaN or AlGan layer, without being limited thereto. The p-type nitride layer may have a stack structure of first and second layers.

The p-type dopant may include at least one selected from among magnesium (Mg), zinc (Zn), and cadmium (Cd). Preferably, magnesium (Mg) is used as the p-type dopant.

Increase in p-type dopant such as Mg content in a nitride can cause increase in nitrogen vacancy concentration. Here, carbon, as a co-dopant, is substituted into a nitrogen vacancy site, causing decrease in nitrogen vacancy concentration. FIG. 4 shows an energy band diagram within a GaN thin film and activation pathways of holes, when a nitride is co-doped with magnesium, that is, the p-type dopant, and carbon. As shown in FIG. 4, holes can be activated along three pathways and ionization of holes in the carbon acceptor level can be facilitated by the magnesium acceptor level, thereby enabling realization of a p-type nitride layer having a high free-hole concentration.

Preferably, the carbon doping concentration ranges from 1×10¹⁷ atoms/cm³ to 1×10¹⁹ atoms/cm³. When the carbon doping concentration is less than this range, substitution of nitrogen vacancy with carbon is insignificant and the nitride layer exhibits n-type properties. When the carbon doping concentration is higher than this range, the nitride has deteriorated crystallinity, thereby causing reduction in free-hole concentration.

In the present invention, the p-type dopant and carbon (C) are doped in c-plane of the nitride. For example, when carbon is doped into GaN, which is a representative nitride, it is necessary for a carbon atom to be substituted into a nitrogen site in order to act as an acceptor. However, since a surface of c-plane of GaN is terminated with a Ga plane, it is difficult for the carbon atom to be substituted into the nitrogen site. As a result, the carbon atom is likely to be substituted into a Ga site. In this case, the carbon atom acts as a donor and eliminates a hole created by the carbon acceptor, thereby causing loss of conductivity. However, according to the present invention, in formation of the p-type nitride layer, a nitrogen source is supplied at a low flow rate, and growth temperature, growth pressure and V/III ratio are adjusted, such that carbon is auto-doped into the nitride layer to increase the free-hole concentration and carbon doping can be achieved in c-plane. In particular, when carbon is auto-doped, Mg can be readily substituted to the Ga site and a probability of substitution of C into an N site is increased, thereby improving the free-hole concentration.

Carbon doping can significantly increase the free-hole concentration of the p-type nitride layer, for example, in the range of 1×10¹⁸ to 1×10¹⁹/cm³.

The transparent electrode layer 160 is formed of a transparent conductive oxide on an upper surface of the p-type nitride layer 150 and may include an element, such as In, Sn, Al, Zn, Ga, or the like. For example, the transparent electrode layer 160 may be formed of any one of ITO, CIO, ZnO, NiO, and In₂O₃.

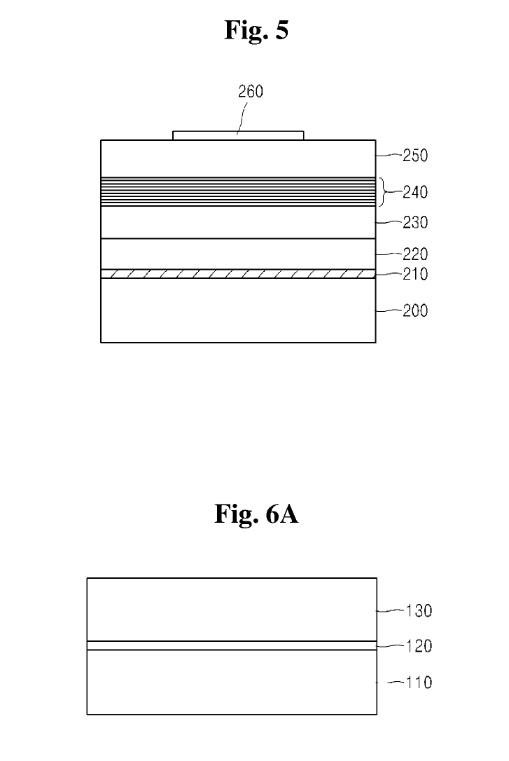

Next, a vertical type nitride semiconductor light emitting device according to a second embodiment of the present invention will be described with reference to FIG. 5. FIG. 5 is a sectional view of the vertical type nitride semiconductor light emitting device according to the second embodiment of the present invention. Here, detailed descriptions of the vertical type nitride semiconductor light emitting device apparent to those skilled in the art will be omitted for clarity.

Referring to FIG. 5, the vertical type nitride semiconductor light emitting device according to the second embodiment includes a refractive layer 210, an ohmic contact layer 220, a p-type nitride layer 230, an active layer 240, an n-type nitride layer 250, and an n-side electrode 260 in an upward direction of a p-side electrode support layer 200.

The p-side electrode support layer 200 is a conductive support member and is required to achieve sufficient dissipation of heat generated during operation of the light emitting device while serving as a p-side electrode. In particular, the p-side electrode support layer 200 is required to have sufficient mechanical strength to support the layers stacked thereon in a manufacturing process including scribing or breaking.

Accordingly, the p-side electrode support layer 200 may be formed of a metal having high thermal conductivity, such as gold (Au), copper (Cu), silver (Ag), and aluminum (Al). The p-side electrode support layer 200 may also be formed of an alloy, which has a similar crystal structure and lattice parameter to such metals so as to minimize internal stress in alloying and has sufficient mechanical strength. For example, the p-side electrode support layer is preferably formed of an alloy including a light metal, such as nickel (Ni), cobalt (Co), platinum (Pt), or palladium (Pd).

The refractive layer 210 is optionally formed on an upper surface of the p-side electrode support layer 200, and may be formed of a metal having high reflectivity, capable of causing light from the active layer 240 to be reflected in an upward direction.

The ohmic contact layer 220 is formed of a metal, such as nickel (Ni) and gold (Au), or a nitride containing such a metal on an upper surface of the reflection layer 210, thereby forming a low resistance ohmic contact. When the ohmic contact layer 220 is formed of a metal, such as nickel (Ni) or gold (Au), there is no need to form the reflection layer 210, since the ohmic contact layer can perform reflection.

Next, the p-type nitride layer 230, the active layer 240, the n-type nitride layer 250, and the n-side electrode 260 are sequentially formed.

Method of Manufacturing Nitride-Based Light Emitting Device

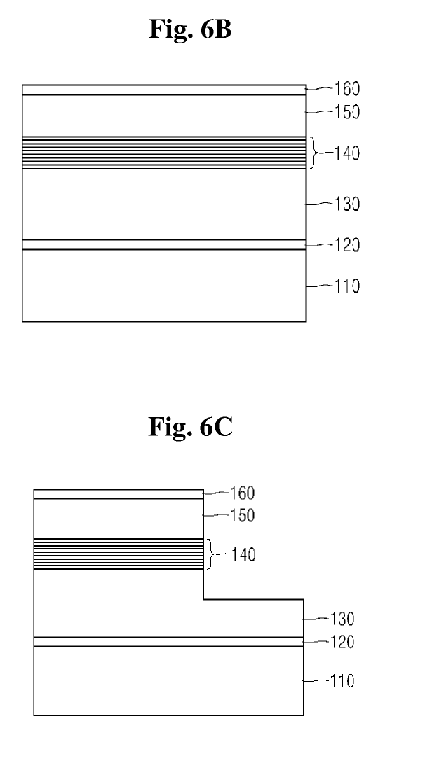

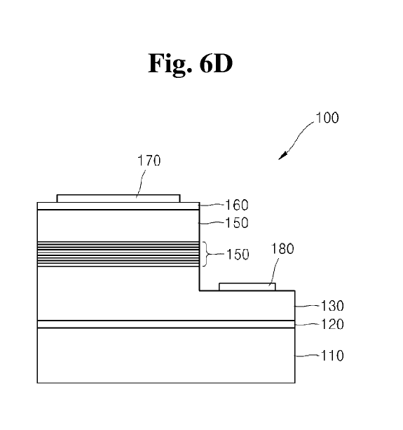

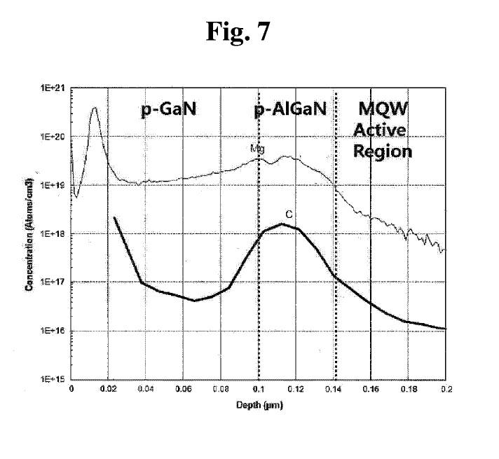

Hereinafter, a method of manufacturing the nitride semiconductor light emitting device according to the first embodiment of the invention will be described in detail with reference to FIGS. 6A to 6D.

To manufacture the nitride semiconductor light emitting device 100 according to the first embodiment, a buffer layer 120 and an n-type nitride layer 130 are sequentially formed on an upper surface of a substrate 110, as shown in FIG. 6A.

The buffer layer 120 may be optionally formed on the upper surface of the substrate 110 to relieve lattice mismatch between the substrate 110 and the n-type nitride layer 130. Here, the buffer layer 120 may be formed of, for example, AlN or GaN.

The n-type nitride layer 130 may be formed by growing an n-GaN layer while supplying silane gas containing an n-type dopant, for example, NH₃, trimethylgallium (TMG), and Si.

As shown in FIG. 6B, the active layer 140 may have a single quantum well structure or a multi-quantum well structure in which quantum well layers and quantum barrier layers are alternately stacked one above another. In this embodiment, the active layer 140 may have a multi-quantum well structure wherein quantum barrier layers and quantum well layers are formed of AlₓGa_{y}In_{z}N (x+y+z=1, 0≦x≦1, 0≦y≦1, 0≦z≦1).

Next, the p-type nitride layer 150 is formed of a nitride co-doped with a p-type dopant and carbon (C). The nitride layer co-doped with the p-type dopant and carbon may be formed by any vapor epitaxial growth method selected from among ALE (Atomic Layer Epitaxy), APCVD (Atmospheric Pressure Chemical Vapor Deposition), PECVD (Plasma Enhanced Chemical Vapor Deposition), RTCVD (Rapid Thermal Chemical Vapor Deposition), UHVCVD (Ultrahigh Vacuum Chemical Vapor Deposition), LPCVD (Low Pressure Chemical Vapor Deposition), MOCVD (Metal Organic Chemical Vapor Deposition), and the like.

Here, decrease in flow rate of ammonia gas, as a nitrogen source, instead of using a separate carbon source, can minimize pre-reaction of an aluminum source or a magnesium source and ammonia used as a nitrogen source, thereby enabling carbon auto-doping without injecting a separate carbon source. Thus, an Mg/C-doped AlGaN layer can be formed using NH₃, trimethyl aluminum (TMAl), trimethylgallium (TMG), and bis(cyclopentadienyl)magnesium (Cp₂Mg) by, for example, MOCVD.

In formation of the p-type nitride layer, the ammonia source is supplied at a lower flow rate than in formation of the n-type nitride layer, preferably at 1 to 15 l/min, most preferably at 5 to 10 l/min If the flow rate of the ammonia source is below the range set forth above, abnormal growth of a thin film can occur. On the contrary, if the flow rate of the ammonia source exceeds the range set forth above, reduction of carbon auto-doping can occur.

When the p-type nitride layer includes Al, the p-type nitride layer is preferably grown under process conditions including a growth temperature of 1000° C. to 1500° C., a growth pressure of 10 mbar to 200 mbar, and a V/III ratio of 100 to 1500. In particular, when Al is present in an amount of 20 mol % or more in Group III elements, it is advantageous that the p-type nitride layer is grown under process conditions including a growth temperature of 1200° C. to 1400° C., a growth pressure of 30 mbar to 100 mbar, and a V/III ratio of 300 to 1200. When the p-type nitride layer does not include Al, the p-type nitride layer may be grown under process conditions including a growth temperature of 900° C. to 1200° C., a growth pressure of 100 mbar to 1013 mbar, and a V/III ratio of 100 to 3000.

If the growth temperature and growth pressure are below the range set forth above, deterioration in crystallinity can occur, which leads to reduction in free-hole concentration, whereas if the growth temperature and growth pressure exceeds the range set forth above, separation of gallium can occur, which leads to deterioration in crystal quality. In addition, if the V/III ratio is below the range set forth above, shortage of a nitrogen source, such as ammonia, can occur, which leads to deterioration in crystallinity, whereas if the V/III ratio exceeds the range set forth above, oversupply of a nitrogen source can occur, which leads to insufficient carbon doping.

The p-type nitride layer may be doped in-situ, without being limited thereto.

Then, the transparent electrode layer 160 is formed of a transparent conductive oxide on an upper surface of the p-type nitride layer 150.

After the transparent electrode layer 160 is formed, some region of the n-type nitride layer 130 may be exposed through lithographic etching and cleaning from one region of the transparent electrode layer 160 to a portion of the n-type nitride layer 130, as shown in FIG. 6C.

After some region of the n-type nitride layer 130 is exposed, a p-side electrode 170 and an n-side electrode 180 are formed on an upper surface of the transparent electrode layer 160 and the exposed region of the n-type nitride layer 130, respectively, as shown in FIG. 6D.

The vertical type nitride semiconductor light emitting device according to the second embodiment may be manufactured using a typical method for producing a vertical type nitride semiconductor light emitting device. In this embodiment, however, the p-type nitride layer (230) is formed of a nitride co-doped with a p-type dopant and carbon (C), as described above.

### EXAMPLE

AlGaN (including 20 mol % of aluminum) was used to form each layer of a nitride-based light emitting device, followed by doping under conditions including a growth temperature of 1100° C., a growth pressure of 60 mbar, a V/III ratio of 1100, and a Cp₂Mg flow rate of 100 sccm. NH₃ was supplied at a flow rate of 10 l/min.

### Comparative Example

AlGaN (including 20 mol % of aluminum) was used to form each layer of a nitride-based light emitting device, followed by doping under process conditions including a growth temperature of 1100° C., a growth pressure of 150 mbar, a V/III ratio of 3000, and a Cp₂Mg flow rate of 100 sccm. NH₃ was supplied at a flow rate of 20 l/min.

### Experimental Example

### Comparison of Carbon Concentration in p-AlGaN Layer and Optical Power of Device

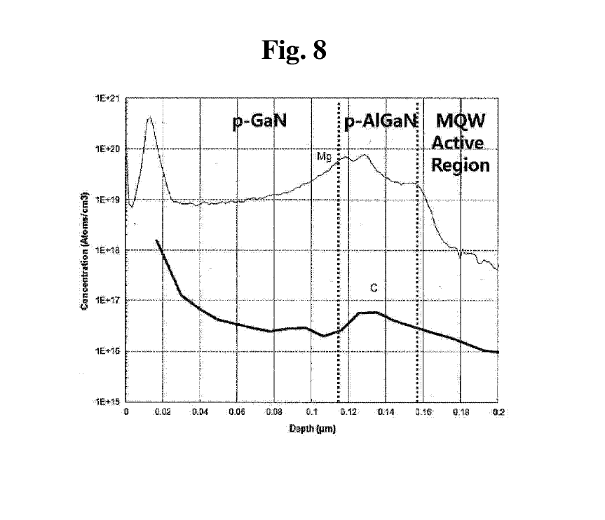

Magnesium (Mg) and carbon (C) profiles in Example and Comparative Example are shown in FIG. 7 and FIG. 8, respectively.

In addition, magnesium and carbon concentrations in the p-AlGaN layer and optical power of chips having a size of 250 nm×600 nm upon operation at 20 mA were measured. The results are shown in Table 1.

TABLE 1

| | Doping amount of Mg | Doping amount | Optical power |
|---|---|---|---|
| | (atoms/cm³⁾ | of C (atoms/cm³) | (mW) |
| Example | 5.0 × 10¹⁹ | 1.0 × 10¹⁸ | 27 |
| Comparative | 7.0 × 10¹⁹ | 6.0 × 10¹⁶ | 21 |
| Example | | | |

In Table 1, it can be seen that the light emitting device of Example exhibited about 30% higher optical power than the light emitting device of Comparative Example. It can be considered that such characteristics were obtained since the p-AlGaN layer was doped with carbon in higher concentration.

Although some embodiments have been provided to illustrate the present invention, it will be apparent to those skilled in the art that the embodiments are given by way of illustration, and that various modifications and equivalent embodiments can be made without departing from the spirit and scope of the present invention. Accordingly, the scope of the present invention should be limited only by the accompanying claims and equivalents thereof.

1. A nitride semiconductor light emitting device comprising:
an n-type nitride layer;
an active layer formed on an upper surface of the n-type nitride layer; and
a p-type nitride layer formed on an upper surface of the active layer, wherein the p-type nitride layer is formed of a nitride co-doped with a p-type dopant and carbon (C).

2. The nitride semiconductor light emitting device according to claim 1, wherein the p-type nitride layer has a higher carbon concentration than the active layer or the n-type nitride layer.

3. The nitride semiconductor light emitting device according to claim 1, wherein carbon is doped in a concentration of 1×10¹⁷ atoms/cm³ to 1×10¹⁹ atoms/cm³.

4. The nitride semiconductor light emitting device according to claim 1, wherein the p-type dopant comprises at least one selected among magnesium (Mg), zinc (Zn), and cadmium (Cd).

5. The nitride semiconductor light emitting device according to claim 1, wherein the p-type dopant and carbon (C) are doped into the nitride via c-plane thereof.

6. The nitride semiconductor light emitting device according to claim 1, wherein the p-type nitride layer has a free-hole concentration in the range of 1×10¹⁸/cm³ to 1×10¹⁹/cm³.

7. The nitride semiconductor light emitting device according to claim 1, wherein the p-type nitride layer is formed of a nitride containing 20 mol % or more of Al in Group III.

8. The nitride semiconductor light emitting device according to claim 1, further comprising:
a buffer layer formed under the n-type nitride layer; and
a substrate formed under the buffer layer.

9. A method of manufacturing a nitride semiconductor light emitting device, comprising:
forming an n-type nitride layer on a substrate;
forming an active layer on the n-type nitride layer; and
forming a p-type nitride layer on the active layer,
wherein, in formation of the p-type nitride layer, a nitrogen source is supplied at a lower flow late than in formation of the n-type nitride layer such that a p-type dopant and carbon (C) are co-doped into the p-type nitride layer.

10. The method according to claim 9, wherein, in formation of the p-type nitride layer, the nitrogen source is supplied at a flow rate ranging from 1 l/min to 15 l/min.

11. The method according to claim 10, wherein the nitrogen source is NH₃.

12. The method according to claim 9, wherein the p-type nitride layer containing Al is grown under process conditions including a growth temperature of 1000° C. to 1500° C., a growth pressure of 10 mbar to 200 mbar, and a V/III ratio of 100 to 1500.

13. The method according to claim 12, wherein the p-type nitride layer comprises a nitride containing 20 mol % or more of Al in Group III.

14. The method according to claim 9, wherein the p-type nitride layer not containing Al is grown under process conditions including a growth temperature of 900° C. to 1200° C., a growth pressure of 100 mbar to 1013 mbar, and a V/III ratio of 100 to 3000.
